(19) United States
(12) Patent Application Publication
(10) Pub. No.: US 2024/0347602 A1
(43) Pub. Date: Oct. 17, 2024

(54) REDUCED STRAIN HETEROEPITAXY ASSEMBLY FOR THREE-DIMENSIONAL DEVICE AND METHOD OF FABRICATION THEREFOR

(71) Applicant: Applied Materials, Inc., Santa Clara, CA (US)

(72) Inventors: Fredrick FISHBURN, Apotos, CA (US); Balasubramanian PRANATHARTHIHARAN, San Jose, CA (US); Abhishek DUBE, Fremont, CA (US); Saurabh CHOPRA, Saratoga, CA (US)

(73) Assignee: Applied Materials, Inc., Santa Clara, CA (US)

(21) Appl. No.: 18/632,003

(22) Filed: Apr. 10, 2024

Related U.S. Application Data
(60) Provisional application No. 63/458,777, filed on Apr. 12, 2023.

(51) Int. Cl. H01L 29/165; H01L 21/02; H01L 21/306; H01L 29/04; H10B 12/00

(52) U.S. Cl. CPC H01L 29/165; H01L 21/02532; H01L 21/30604; H01L 29/045; H10B 12/00

(57) ABSTRACT

A three-dimensional semiconductor (3D) device. The 3D device may include a substrate, and a monocrystalline layer stack. The monocrystalline layer stack may include at least one monocrystalline semiconductor layer, separated from, and disposed over a main surface of the substrate. The 3D device may further include a plurality of epitaxial heterostructures, integrally grown from the at least one monocrystalline semiconductor layer. As such, a first epitaxial heterostructure may be disposed on a lower surface of the at least one monocrystalline semiconductor layer, facing the substrate, and wherein a second epitaxial heterostructure may be disposed on an upper surface of the monocrystalline semiconductor layer, opposite the lower surface.

### RELATED APPLICATIONS

This application claims priority to U.S. Provisional Patent Application Ser. No. 63/458,777, filed Apr. 12, 2023, entitled REDUCED STRAIN HETEROEPITAXY ASSEMBLY FOR THREE-DIMENSIONAL DEVICE AND METHOD OF FABRICATION THEREFOR, and incorporated by reference herein in its entirety.

### FIELD OF THE DISCLOSURE

The disclosure relates generally to three-dimensional semiconductor devices, and in particular, three-dimensional devices that employ heteroepitaxial structures.

### BACKGROUND OF THE DISCLOSURE

As semiconductor devices such as dynamic random access memory (DRAM) and logic devices, including complementary metal oxide semiconductor field effect transistors (CMOS), and other devices, reach the limit of lateral scaling, further device improvement may hinge upon formation of three-dimensional (3D) semiconductor devices (also referred to herein as 3D devices). In the case of CMOS as well as DRAM, some 3D devices, including three-dimensional memory devices (for example, three-dimensional dynamic random access memory) may employ heterostructures that include an alternating sequence of a semiconductor layer (such as monocrystalline silicon) with a semiconductor alloy layer, such as monocrystalline Si:Ge alloy (also referred to herein as SiGe).

In some approaches for fabricating 3D devices, a semiconductor alloy layer such as SiGe may be used in part or as a whole as a sacrificial layer, where the sacrificial layer can be readily removed by known selective etching procedures at the appropriate fabrication stage. This approach has been adopted in schemes to fabricate 3D DRAM, as well as CMOS, such as gate-all-around devices. By fabricating heterostructures that include multiple sequences of Si/SiGe layers, for example, multiple devices may be stacked in a vertical manner, where a given device is fabricated from a given silicon layer of the heterostructure.

One issue encountered with fabricating 3D devices based upon growing heteroepitaxial layers is the strain induced between the different crystalline materials. For example, when growing Si/SiGe heteroepitaxy there is a strain induced from the mismatch in lattice between monocrystalline Si and SiGe alloys. For relatively thin layers of Si or SiGe, and for SiGe alloys having relatively lower Ge content, the lattice mismatch does not present a large challenge. However, for relatively thicker layers, the lattice mismatch can create enough strain on the crystal lattice to cause defects in the single crystal structure, leading to effects such as relaxation. Relaxation is a loss of the single crystal structure which results in crystal defects and may include degradation on device performance.

In the case of heterostructures in particular, for compositions as low as 30% Ge in the SiGe alloy layer, the critical thickness for relaxation may be in the order of 1 micrometer, depending upon the relative thickness of the Si layer and SiGe layer. Note moreover that for a reliable selective etching processes, a minimum Ge content is needed to ensure selective removal of the sacrificial SiGe layer. Thus, scaling of 3D devices based upon Si/SiGe heterostructures may be limited in total height, and thus may be limited in the number of device layers than be fabricated in the vertical direction.

With respect to these and other considerations, the present disclosure is provided.

### BRIEF SUMMARY

In one embodiment, a three-dimensional semiconductor device is provided, including a substrate, and a monocrystalline semiconductor layer stack. The monocrystalline semiconductor layer stack may include at least one monocrystalline semiconductor layer, separated from, and disposed over a main surface of the substrate, and a plurality of epitaxial heterostructures, integrally grown from the at least one monocrystalline semiconductor layer. As such, a first epitaxial heterostructure may be disposed on a lower surface of the at least one monocrystalline semiconductor layer, facing the substrate, and wherein a second epitaxial heterostructure is disposed on an upper surface of the monocrystalline semiconductor layer, opposite the lower surface.

In another embodiment, a method of forming a three-dimensional semiconductor device is provided. The method may include providing a monocrystalline semiconductor substrate, and growing an epitaxial macrostack on the monocrystalline semiconductor substrate, the epitaxial macrostack comprising a set of monocrystalline semiconductor layers that alternate with a set of semiconductor alloy layers. The method may further include etching an array of slots to form an array of trenches that extend through the epitaxial macrostack. The method may include selectively etching the epitaxial macrostack to remove the set of semiconductor alloy layers, wherein the epitaxial macrostack forms a monocrystalline semiconductor layer stack comprising a set of semiconductor layers that are separated from one another by a set of lateral cavities. The method may also include selectively etching a main surface of the set of monocrystalline semiconductor layers, wherein a height of the set of lateral cavities is increased, so as to form a set of device regions; and growing an epitaxial device heterostructure on exposed surfaces of the set of semiconductor layers within the set of device regions.

In a further embodiment, a three-dimensional memory device is provided, including a silicon substrate, and a monocrystalline semiconductor layer stack that has a plurality of monocrystalline silicon layers that are disposed over a main surface of the silicon substrate, and are separated from one another. The three-dimensional memory device may also include a plurality of epitaxial heterostructures, integrally grown from the plurality of monocrystalline silicon layers. As such, a first epitaxial heterostructure may be disposed on a lower surface of a given monocrystalline silicon layer, and wherein a second epitaxial heterostructure is disposed on an upper surface of the monocrystalline silicon layer, opposite the lower surface.

### BRIEF DESCRIPTION OF THE DRAWINGS

FIG. 1 shows an exemplary three-dimensional device, in cross-section, according to some embodiments of the disclosure;

FIGS. 2A, 2B, 2C, 2D, 2E and 2F show an exemplary three-dimensional device at various stages of processing, according to embodiments of the disclosure;

FIG. 2C-2 shows an alternative configuration of the three dimensional device at the stage of processing corresponding to FIG. 2C;

FIG. 2G shows another exemplary three-dimensional device, in cross-section, according to some embodiments of the disclosure;

FIGS. 2H and 2I show alternative embodiments of a slot structure; and

FIG. 3 depicts an exemplary process flow.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not to be construed as being limited to the embodiments set forth herein. Instead, these embodiments are provided so this disclosure will be thorough and complete, and will fully convey the scope of the system and method to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for reduced strain in three-dimensional devices formed using heteroepitaxy.

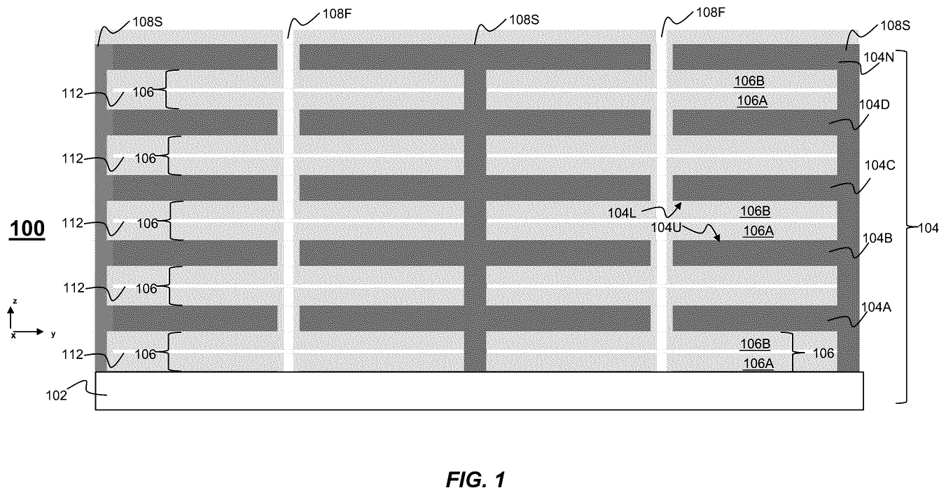

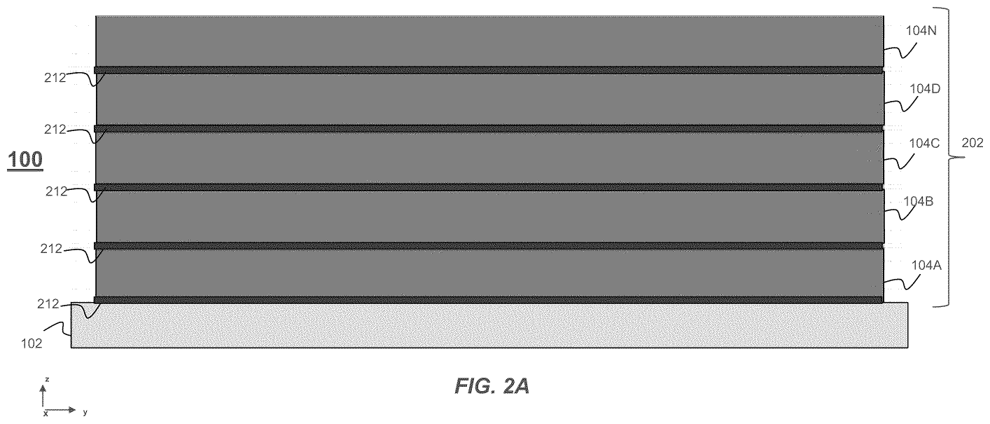

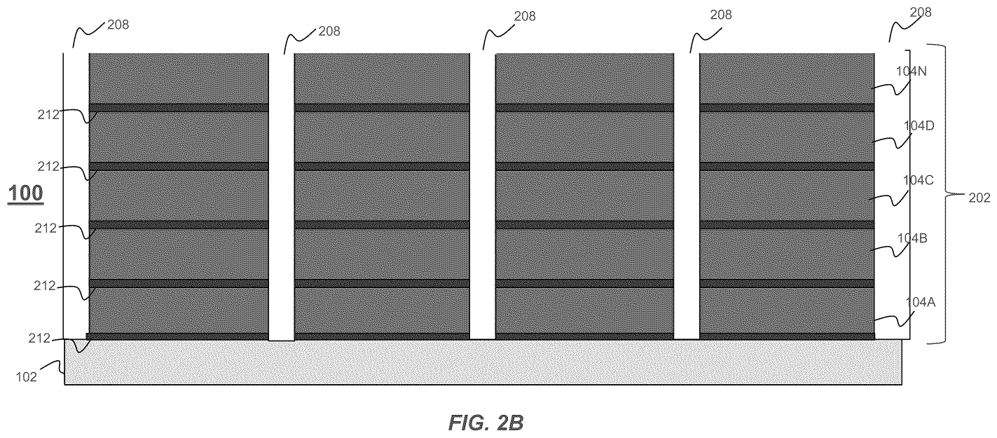

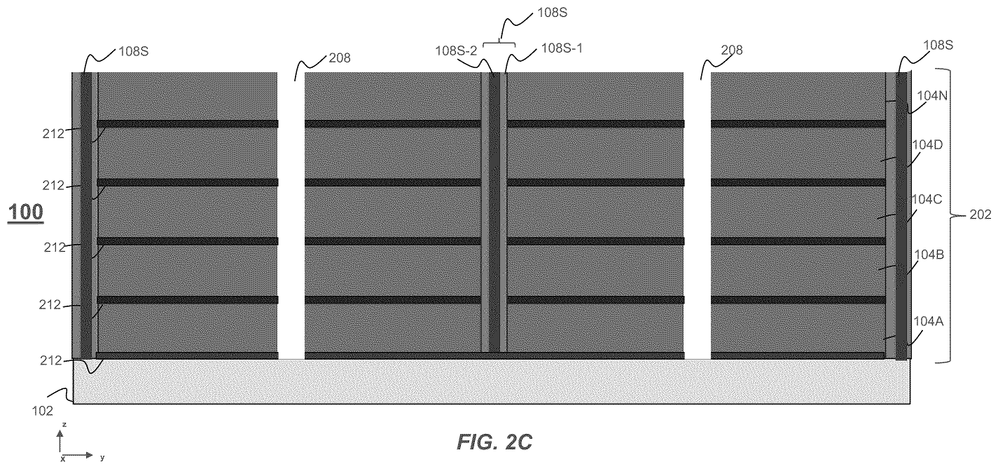

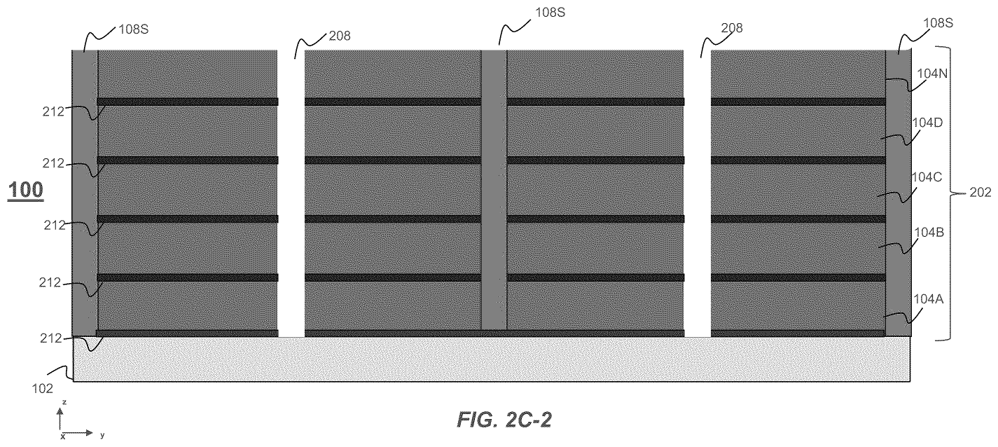

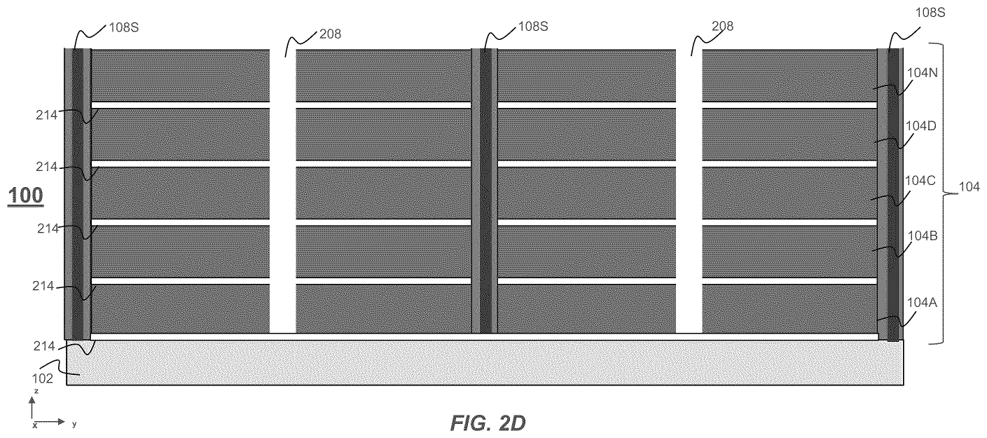

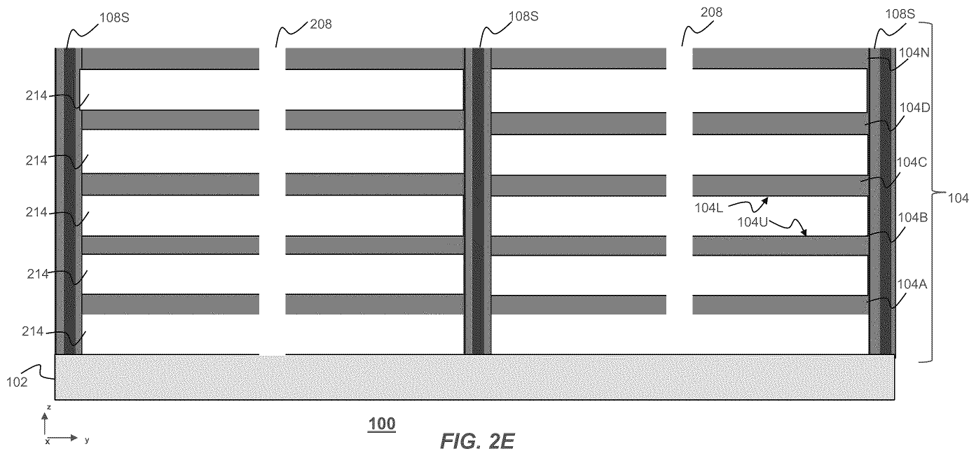

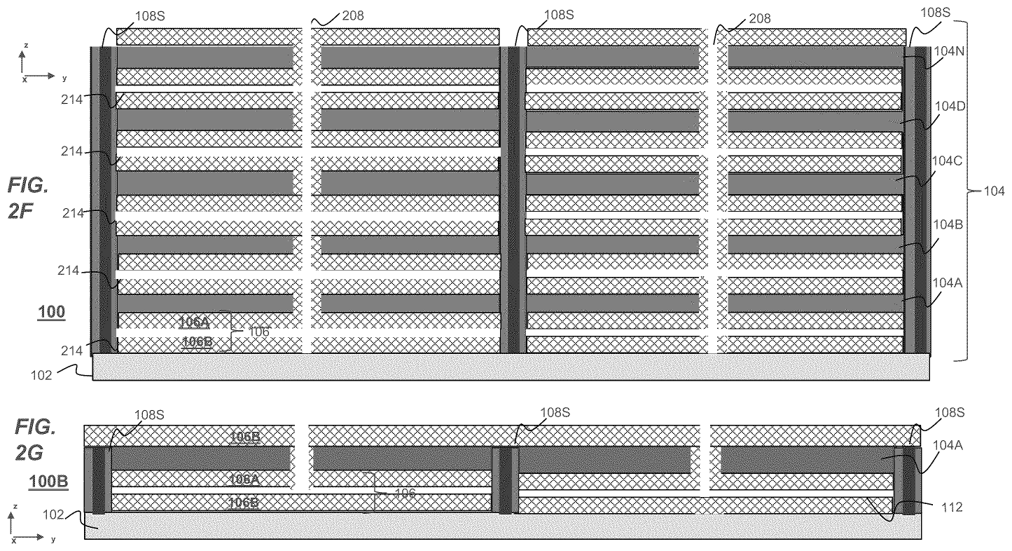

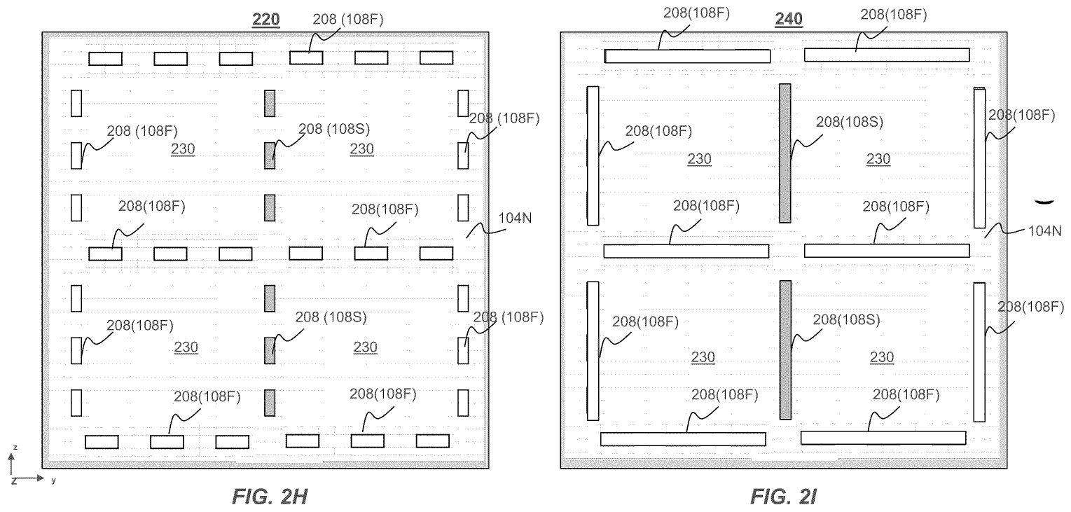

FIG. 1 shows an exemplary three-dimensional device, in cross-section, according to some embodiments of the disclosure, while FIGS. 2A-2F show an exemplary device at various stages of processing, according to embodiments of the disclosure. Turning now to FIG. 1, there is shown a three-dimensional semiconductor device, denoted as device 100, according to embodiments of the disclosure. The device 100 may be fabricated using a substrate 102, where the substrate 102 is a monocrystalline semiconductor material, such as silicon. The device 100 may represent a three-dimensional assemblage of individual devices, such as a 3D memory device, a 3D logic device, and so forth. In one example, the device 100 may be a 3D DRAM device, where arrays of memory cells are arranged in a plurality of layers, stacked one upon another, along the Z-direction of the Cartesian coordinate system shown. Within a given layer, the memory cells may also be arranged in a two dimensional array (within the X-Y plane).

As illustrated, the device 100 includes a plurality of monocrystalline semiconductor layers, shown collectively as monocrystalline semiconductor layer stack 104, where the individual monocrystalline semiconductor layers are shown as layer 104A, layer 104B, layer 104C, layer 104D, and layer 104N. In various non-limiting embodiments, the value of N may range from 2 to 10. The monocrystalline semiconductor layer stack 104 may be formed of the same material as substrate 102 in various embodiments. As described in more detail with respect to FIGS. 2A-2H, the monocrystalline layer stack may be formed by epitaxial growth of a semiconductor material on the substrate 102. As such, the monocrystalline semiconductor layer stack 104 may be considered to constitute a plurality of separate, internal monocrystalline ‘substrates,’ where further epitaxial processing may be performed to grow device structures on the surfaces of these internal monocrystalline substrates. In particular, the individual monocrystalline layers of the monocrystalline semiconductor layer stack 104 are separated from one another along the Z-direction within a vertical stack having a desired number of layers to make up the monocrystalline semiconductor layer stack 104.

The device 100 may further include a plurality of heteroepitaxial regions, shown as device regions 106. The device regions 106 may be regions where active semiconductor devices, such as memory structures, logic transistors, and related components are formed. According to various embodiments, a device region 106 may include two regions, at least partially separated from one another, and designated by region 106A and region 106B. In the convention of FIG. 1, the region 106A may be formed by epitaxial growth of an upper epitaxial heterostructure on an upper surface 104U of a given monocrystalline layer, while the region 106B may be formed by epitaxial growth of a lower epitaxial heterostructure on a lower surface 104L of a given monocrystalline layer. The region 106B may be separated from region 106A by a lateral gap 112, which gap may be filled with a dielectric material. While layer 104A is shown as disposed directly on substrate 102, in some embodiments a lowest monocrystalline semiconductor layer of an epitaxial macrostack may be separated from a substrate by a heterostructure.

The device 100 may also include a plurality of vertical support structures, shown as vertical support structures 108S, which structures extend along a first direction, meaning along the Z-direction. The vertical support structures 108S may extend through most or all of the monocrystalline layer stack 104, and are spaced from one another along a second direction, in this case, along the Y-direction, perpendicular to the Z direction. As shown, the vertical support structures 108S may connect the plurality of monocrystalline semiconductor layers of the monocrystalline semiconductor layer stack 104 to one another, and may thus provide mechanical support to the layers 104A-104N. In addition to the vertical support structures 108S, the device 100 may include a plurality of vertical fill structures, shown as vertical fill structures 108F, spaced from one another along the Y-direction. As detailed below, the vertical support structures 108S and the vertical fill structures 108F divide the layers of the monocrystalline semiconductor layer stack 104 into a three-dimensional array of monocrystalline device regions.

Turning to FIG. 2A there is shown an example of the device 100 at one stage of formation or processing. In this example, an epitaxial macrostack 202 has been grown on the substrate 102, where the substrate 102 represents a monocrystalline semiconductor substrate as discussed previously. As shown, the epitaxial macrostack 202 is formed of the monocrystalline layer stack 104, discussed above. As shown the layers 104A-104N, alternate with a set of semiconductor alloy layers along the Z-direction, where the semiconductor alloy layers are represented by layers 212. In one example, the substrate 102 is a monocrystalline silicon substrate, while the layers 104A-104N are monocrystalline silicon layers formed by epitaxial growth, using the substrate 102 as the initial template for growth, and the layers 212 represent Si₁₋ₓ Geₓ alloy layers. An example of a suitable values for x are 0.12 to 0.30 (meaning 12% to 30% Ge), with particular examples of 0.15 to 0.25.

As such, each of the layers represents a monocrystalline layer that is grown heteroepitaxially on a subjacent layer (except for the layer 104,A grown homoepitaxially on the substrate 102.

According to some non-limiting embodiments, an exemplary thickness for the layers 104A-104N at this stage of processing may lie in the range of 5 mm to 10 mm, and in particular cases 8 mm. According to some non-limiting embodiments, an exemplary thickness for the layers 212 may lie between 8 nm to 30 nm and more particularly 10 nm to 20 nm, such as 15 nm. In one embodiment, a thickness of layer 212 is 15 nm, while the mole fraction of Ge is 0.20 (80% Si/20% Ge).

In an example, an epitaxial macrostack 202 may be formed of alternative layers of 8 mm Si and 20 nm SiGe, with a total of five silicon layers, meaning a macrostack formed of a layer 104A, layer 104B, layer 104C, layer 104D, and layer 104E. In this example, the resulting elastic stress imparted to a 400 mm wafer is estimated to be impart a bow of just 80 mm. At this amount of bowing, subsequent wafer processing to form devices on the substrate 102 is not unduly affected. Moreover, the stress generated by an 20 nm SiGe layer alternating with a 8 mm Si will not be sufficient to generate relaxation in the epitaxial macrostack 202.

Turning to FIG. 2B, there is shown a subsequent instance after the stage of FIG. 2A, where an array of trenches that extend through the epitaxial macrostack 202 is formed. These trenches are shown as trenches 208, and may extend at least through the layer 212, closest to the substrate 102. The trenches 208 may be formed by etching the epitaxial macrostack 202 based upon a slot pattern formed on an upper surface of the epitaxial macrostack 202, as further discussed with respect to FIG. 2H and FIG. 2I.

Turning to FIG. 2C, there is shown a subsequent instance after the instance of FIG. 2B, where support material is formed within select trenches of the trenches 208, to form the vertical support structures 108S. In one example, the vertical support structures 108S may be formed in every other of the trenches 208, along the Y-direction as shown. In some embodiments, the support material of support structures may include an epitaxial layer of semiconductor, such as silicon, grown as a liner layer 106S-1 on the vertical sides (such as the X-Z plane) of the layers 104A-104N and layers 212. The epitaxial layer may be grown to a determined thickness, leaving a portion of the trenches 208 open. The middle portions 108S-2 of the trenches 208 may be filled with a material such as silicon nitride. As an example, in some non-limiting embodiments the trenches 208 may be patterned to be 2 mm wide along the Y-direction and may be filled with a growth of 0.5 mm silicon, grown on each vertical surface of the trenches 208, followed by filling with silicon nitride the remaining 1.0 mm-wide cavity in the middle of trenches 208. In other embodiments, the trenches 208 may be filled with an SiN liner and silicon oxide filler. In some embodiments, SiON, Al2O₃, HfO₂, ZrO2 may be used in any suitable combination for filling select trenches of the trenches 208 at the instance of FIG. 2C, to form the vertical support structures 108s.

An advantage of forming the vertical support structures 108S with a liner 108S-1 of epitaxial silicon is that the liner 108S-1 may serve as template for subsequent growth of a semiconductor heterostructure based upon Si/SiGe, discussed with respect to FIG. 2F below. As such, the presence of a monocrystalline silicon surface for the liner of the vertical support structures 108S may prevent defective growth of monocrystalline heterostructure material that may otherwise take place, where the liner 108S-1 fabricated from other material, such as oxide or nitride.

In some embodiments, the middle portions 108S-2 of the vertical support structures 108S may be omitted, such that a vertical support structure 108S is grown of a single material, such as monocrystalline silicon. This configuration is illustrated in the embodiment of a support structure in FIG. 2C-2. In this configuration, epitaxial silicon may be grown from opposing sidewalls of trenches 208 until the trenches 208 are closed.

Turning to FIG. 2D there is shown a subsequent instance of the processing of device 100, where the epitaxial macrostack 202 has been selectively etched to remove the set of semiconductor alloy layers, meaning the layers 212. As such, a monocrystalline semiconductor layer stack 104 is formed, described above, which layer stack includes a set of lateral cavities is formed, shown as lateral cavities 214, where the lateral cavities 214 occupy a similar space in the epitaxial macrostack 202 as previously occupied by the layers 212. In the case of layers 212 being formed of SiGe, the layers 212 may be selectively removed by known etchants that are selective to SiGe with respect to Si. As such, the height of the lateral cavities 214 may be on the order of a few nm along the Z-direction, such as 15 nm to 50 nm in some embodiments.

Turning to FIG. 2E there is shown a subsequent instance of the processing of device 100, where a main surface, meaning the surface along the X-Y plane, is selectively etched. In this example, the selective etching causes the height of the lateral cavities 214 to increase substantially, such as to a height of one micrometer or more. The lateral cavities now define the space for the device regions 106, discussed previously with respect to FIG. 1. In some non limiting embodiments where the layers 104A-104N are single crystalline silicon, the crystal structure of the layers 104A-104N will be formed in epitaxial fashion with the underlaying substrate, substrate 102. According to embodiments of the disclosure, the main plane of substrate 102, meaning the X-Y plane, will be the (100) crystallographic plane, meaning that the upper surface 104U and lower surface 104L of each of layers 104A-104N will present the (100) crystallographic surface. In this configuration, according to some embodiments, an etchant such as tetramethylammonium hydroxide (TMAH) or NH₄OH may be used to selectively etch the lateral cavities 214. Such etchants are known to selectively etch the <100>silicon plane 20 times faster than the <110> silicon plane. Thus, the X-Y planar surfaces (<100>) will etch much faster than the X-Z surfaces (vertical surfaces of the layers 104A-104N, which surfaces correspond to the <110> plane). As such, the vertical sidewalls of trenches 208 may be etched just on the order of tens of nm, while the horizontal surfaces (X-Y plane) are etched up to one micrometer to a few micrometers.

Turning to FIG. 2F there is shown a subsequent instance where an epitaxial heterostructure has been grown on exposed surfaces of the layers 104A-104N within the device regions 106. On either side of a given layer, of the layers 104B-104N, and an upper side of layer 104A, a same heterostructure may be grown simultaneously, using known heteroepitaxial growth techniques. In some examples, the heterostructure may be composed of a plurality of memory layers, where a given memory layer may include a monocrystalline semiconductor layer and monocrystalline semiconductor alloy layer. In some non-limiting embodiments, a memory layer may be a Si/SiGe couple having a total thickness of 80 nm. In some embodiments, up to 8 memory layers, 16 memory layers, or 32 memory layers may be grown within the device region 106. As noted, after formation of heterostructures within the device region 106, the lateral gaps 112 may be filled with a dielectric material, and portions of the trenches 208 not previously filled may be filled with a dielectric material, so as to form the vertical fill structures 108F.

In one example, where the layers 104A-104N are thinned from an initial thickness of 8 mm to 2.8 mm, the resulting lateral cavities 214 will have a final height of approximately 5.2 mm. As such, the lateral cavities 214 will have room to accommodate growth of a heterostructure having a thickness of somewhat less than 2.6 mm on the upper surface 106U and lower surface 106L of each of the layers 104A-104N. Accordingly, in the example of a 80 nm Si/SiGe memory layer, a total of 32 memory layers (giving a heterostructure thickness of 32×80 nm, or 2.56 mm) may be formed in each heterostructure formed on each of the upper surface 106U and lower surface 106L, for a total heterostructure thickness of 5.12 mm within the lateral cavities having a 5.2 mm height.

Note that in the above example a total number of vertically stacked 80 nm memory units of 32, or a total thickness of 2.56 mm in the heterostructure, may represent an upper limit for growing a low strain, low defect Si—SiGe heterostructure. Of course this exact limit may depend upon the relative thickness of Si layer to SiGe layer in the heterostructure as well as the relative molar fraction of Ge in the SiGe layer. In the present embodiments, the height of the lateral cavities 214 may be designed according to the total planned thickness for the heterostructure to be grown therein.

In an example of five layers for the layers 104A-104N, having an initial thickness of 8 mm, a 40 mm Si-SiGe epitaxial stack structure that has 320x memory layers contained therein can be formed from heteroepitaxial growth of 4-layer or 2-layer memory stack repeated 32 times. Depending upon the cell design a given 2 layer stack or 4 layer stack may be configured as follows. A 2 layer stack may be formed of 10 nm SiGe+70 nm Si, while a 4 layer stack may be formed of 10 nm SiGe/20 nm Si/10 nm SiGe/40 nm Si.

In one aspect, the final structure of a device such as device 100 can be considered to be formed of multiple semiconductor substrates, where each of layers 104A-104N mimics an individual monocrystalline semiconductor substrate that acts as a template for epitaxial growth of heterostructures similarly to bulk silicon substrates. As detailed further with respect to FIGS. 2H and 2I, these semiconductor substrates are supported at the periphery of areas that define device regions, such as memory arrays. Moreover, each ‘substrate’ (at least for layers 104B-104N in the device 100) acts as a template for epitaxial growth on both an upper surface 104U and lower surface 104L. Thus, each ‘substrate’ can support the growth of a total number of heteroepitaxial layers that is twice the thickness limit for strain free growth. In other words, in the example of low strain, low defect Si/SiGe heterostructures, given a thickness limit of 2.56 mm, a total of 5.12 mm may be grown from a single layer of layers 104A-104N.

While the above embodiments reflect a reduced strain heteroepitaxial assembly based upon multiple monocrystalline semiconductor layers, formed above a substrate, the present embodiments are not limited thereto. In one case, a single layer, meaning a layer 104A, may be formed using a macrostack formed of 20 nm SiGe +8 mm Si can be deposited on a silicon substrate, and from this structure, 96x memory layers can be fabricated from heteroepitaxial growth of a 80 nm Si/SiGe bilayer repeated 32 times for a total thickness of 2.56 mm. An example of this scenario is shown in FIG. 2G. In the device 100B shown therein, because an epitaxial heterostructure composed of a 32X-heteroepitaxial stack can be formed on both sides of a layer 104A, and on the upper surface of the bulk silicon substrate, subjacent the layer 104A, a total of 96X memory layers can be formed without exceeding the 32X thickness limit for low relaxation, low defect growth. In this regard, note that the layer 104A in the embodiments of FIGS. 1-2F does not function as a separate ‘substrate’ as layers 104B-104N, in that the layer 104A is grown directly on the substrate 102, and therefore no cavity is formed below the layer 104A in FIG. 1. In the embodiment of FIG. 1G, the assumption is that a sacrificial SiGe was formed directly on the substrate 102, removed, and then the substrate 102 and layer 104A were etched to form a cavity containing the device region 106.

Turning now to FIG. 2H and FIG. 2I there are shown a plan view of a top surface of the device 100 in alternative configurations of slot patterns for forming the vertical fill structures 108F and vertical support structures 108S. In the arrangement 220, the initial slot pattern is characterized by a plurality of rectangular slots arranged around the sides of a rectangular device region, shown as device region 230 that is shaped as a rectangle. In one example, the slots represent the planar cross section of the trenches 208 may have an initial dimension of 2 mm by 8 mm, and are arranged in rows as shown, with short sides of adjacent slots facing one another. In one non-limiting example, the device region 230 may be a memory array having a width and a length of 40 mm.

In the arrangement 240, the initial slot pattern is characterized by a single rectangular slot arranged on a given side of a rectangular device region, shown as device region 230. In one example, the slots may have an initial dimension of 2 mm by 30 mm. In both of the arrangement 220 and the arrangement 240, the vertical support structures are arranged along a first edge of a given rectangular device region, while the plurality of vertical fill structures are arranged along a second edge, a third edge, and a fourth edge of the given rectangular device region.

Note that the width and length of the slots, and the overall slot pattern may be arranged to optimize processing of a device to be formed, including processes for selective removal or filling of material in trenches and cavities formed within the three-dimensional device. Moreover, the relative fraction of the slots that are used for vertical support structures 108S, and the relative arrangement of the support structures may be chosen according to considerations such as providing sufficient mechanical integrity to a three-dimensional device, and ease or processing subjacent structures, such as lateral cavities.

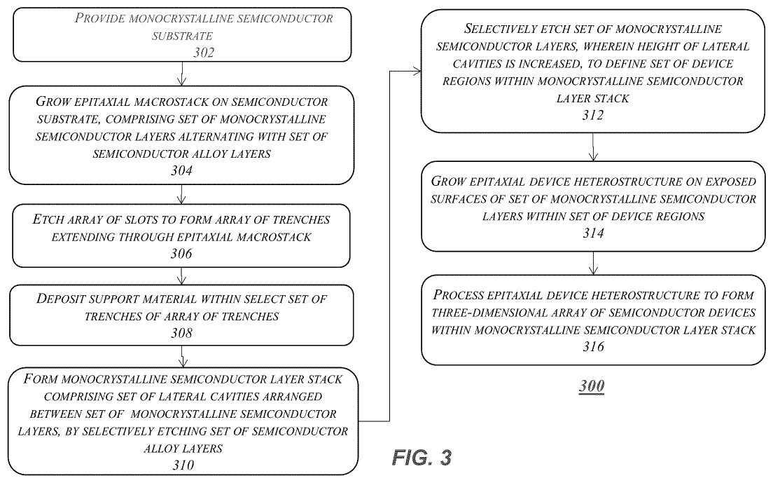

FIG. 3 depicts an exemplary process flow 300. At block 302 a monocrystalline substrate is provided, such as silicon, Si:C, or other semiconductor substrate. In particular embodiments, the monocrystalline substrate may be silicon wafer having a main surface that presents the (100) crystallographic plane.

At block 304 an epitaxial macrostack is grown on the semiconductor substrate, comprising a set of monocrystalline semiconductor layers alternating with set of semiconductor alloy layers. The monocrystalline semiconductor layers may constitute monocrystalline silicon in some embodiments, while the semiconductor alloy layers are formed of monocrystalline SiGe alloy, such as Si₁₋ₓGeₓ where x ranges from 0.12 to 0.30. A useful feature is that the set of semiconductor alloy layers exhibit the same crystal structure as the set of monocrystalline semiconductor layers and can be selectively etched with respect to the set of semiconductor layers with a high degree of selectivity, such as 10:1 or greater. The initial thickness of the monocrystalline semiconductor layers in the epitaxial macrostack may be in the range of 5 mm to 10 mm in some non-limiting embodiments. The thickness of the semiconductor alloy layers may range from 5 nm to 10 nm in other non-limiting embodiments. The number of monocrystalline semiconductor layers and semiconductor alloy layers may range from one to ten according to various non-limiting embodiments.

At block 306 the operation is performed to etch an array of slots to form an array of trenches extending through the epitaxial macrostack. In some embodiments, the array of trenches may extend at least to the semiconductor alloy layer closest to the substrate. In various embodiments, the array of trenches may be arranged in a surface pattern that defines a plurality of semiconductor device areas as seen in plan view of the substrate.

At block 308, a support material is deposited within a select set of trenches of the array of trenches, in order to form support structures. In some examples, the select set of trenches may be arranged in a regular pattern, such as bounding every other edge of a device area along a given direction. In some embodiments, the select set of trenches for forming the support structures may be formed just along an “X” edge of device regions, and not along a “Y” edge. In some embodiments, the support structure may be formed by growing an outer layer of epitaxial silicon on vertical sidewalls of the select set of trenches, followed by depositing an inner layer of silicon nitride in the middle of the trenches.

At block 310, a monocrystalline semiconductor layer stack is formed, having a set of lateral cavities that are formed between the set of monocrystalline semiconductor layers of the epitaxial macrostack, by selectively etching the set of semiconductor alloy layers. The selective etching may take place by providing an etchant through the open trenches that are not filled with the support structures. As such, the selective etching may remove substantially all of the semiconductor alloy layer, exposing opposing surfaces of adjacent semiconductor layers of the epitaxial macrostack. In this manner, the monocrystalline semiconductor layer stack is formed, where the layers of the set of monocrystalline semiconductor layers are separated from one another by the set of lateral cavities.

At block 312, the set of monocrystalline semiconductor layers is selectively etched, wherein the height of the lateral cavities is increased, to define a set of device regions within the monocrystalline semiconductor layer stack. In particular, an etchant may be provided through the open trenches into the lateral cavities where the etchant is configured to etch the exposed surfaces of the semiconductor layers. In one example, TMAH may be used as an etchant, so that exposed (100) surfaces of silicon layers are selectively etched, which surfaces are parallel to the main plane of the semiconductor layers. Thus, the semiconductor layers of the monocrystalline semiconductor layer stack will be selectively etched along the vertical direction to increase the height of the lateral cavities, from an initial height of a few tens of nm, to a final target height, such as 4 mm-6 mm. On the other hand, vertical surfaces, such as the edge of open trenches, will present (110) crystallographic planes of silicon, which planes etch much slower (˜20X slower than (100) surfaces. Thus, the widths of the trenches need not be significantly increased during the selective etching to form the device regions.

At block 314, an epitaxial device heterostructure is grown on exposed surfaces of the set of monocrystalline semiconductor layers within the expanded lateral cavities that define the set of device regions, as defined by the lateral cavities. For example, on a given semiconductor layer, the heterostructure may be grown both on an upper surface and lower surface. Thus, given a thickness limit for low defect, low relaxation monocrystalline semiconductor growth, each semiconductor layer of the monocrystalline semiconductor layer stack may act as a two-sided substrate where the total heterostructure thickness is twice the thickness limit. Given N number of semiconductor layers, the total heterostructure thickness for a three-dimensional device grown from the monocrystalline semiconductor layer stack may be equal to 2N+1 times the thickness limit for low defect, low relaxation monocrystalline semiconductor growth.

At block 316, the epitaxial device heterostructure is processed to form a three-dimensional array of semiconductor devices within the monocrystalline semiconductor layer stack,

In view of the foregoing, at least the following advantages are achieved by the embodiments disclosed herein. A first advantage is provided in that the epitaxial macrostructure architecture of the present embodiments decouples the total number of device layers that can be fabricated in a 3D device from the known thickness limit for fabricating low strain, low defect, low relaxation heterostructures. In other words, the total thickness of a low strain heterostructure and therefore the total number of device layers that can be fabricated can be increased just by increasing the number of monocrystalline semiconductor layers in the epitaxial macrostack. A second advantage afforded by the present embodiments is the ability to efficiently scale up the number of low strain device layers in a 3D device, since each monocrystalline layer of the monocrystalline semiconductor layer stack serves as a template for growth of two separate heterostructures. Thus, for a given heteroepitaxial growth process, such as growing 32X Si/SiGe couples, a total of 320X layers may be grown simultaneously within a five-silicon layer monocrystalline semiconductor layer stack a, with the maximum strain of the resulting 3D device still dictated just by the individual strain within a given 32X heterostructure grown on each side of a given silicon layer.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. A three-dimensional semiconductor device, comprising:
a substrate; and
a monocrystalline semiconductor layer stack, comprising:
at least one monocrystalline semiconductor layer, separated from, and disposed over a main surface of the substrate; and
a plurality of epitaxial heterostructures, integrally grown from the at least one monocrystalline semiconductor layer, wherein a first epitaxial heterostructure is disposed on a lower surface of the at least one monocrystalline semiconductor layer, facing the substrate, and wherein a second epitaxial heterostructure is disposed on an upper surface of the monocrystalline semiconductor layer, opposite the lower surface.

2. The three-dimensional semiconductor device of claim 1, wherein the monocrystalline semiconductor layer stack comprises:
a plurality of monocrystalline semiconductor layers, mutually separated from one another along a first direction within a vertical stack,
wherein a plurality of heteroepitaxial regions are arranged in alternating fashion with the plurality of monocrystalline semiconductor layers, wherein a given heteroepitaxial region of the plurality of heteroepitaxial regions comprises a crystalline semiconductor/semiconductor alloy stack,
wherein the given heteroepitaxial region comprises an upper epitaxial heterostructure, integrally grown from a first monocrystalline semiconductor layer of the plurality of monocrystalline semiconductor layers, and
wherein the given heteroepitaxial region comprises a lower epitaxial heterostructure, integrally grown from a second monocrystalline semiconductor layer of the plurality of monocrystalline semiconductor layers, the second monocrystalline semiconductor layer being disposed immediately subjacent the first monocrystalline semiconductor layer.

3. The three-dimensional semiconductor device of claim 1,
wherein the substrate comprises monocrystalline silicon having a first main surface parallel to a (100) crystallographic plane, wherein the at least one monocrystalline semiconductor layer comprises silicon, and
wherein the first epitaxial heterostructure and the second epitaxial heterostructure comprise a Si/SiGe structure.

4. The three-dimensional semiconductor device of claim 1, further comprising:
a plurality of vertical support structures, extending along a first direction, perpendicularly to a main plane of the substrate, and spaced from one another along a second direction, perpendicular to the first direction, the plurality of vertical support structures connecting the at least one monocrystalline semiconductor layer to the substrate; and
a plurality of vertical fill structures, extending along the first direction, spaced from one another along the second direction,
wherein the plurality of vertical support structures and the plurality of vertical fill structures separate the at least one monocrystalline semiconductor layer into a three-dimensional array of monocrystalline device regions.

5. The three-dimensional semiconductor device of claim 4, wherein the plurality of vertical fill structures comprise an outer layer of epitaxial silicon and an inner layer of silicon nitride.

6. The three-dimensional semiconductor device of claim 4, wherein the plurality of vertical fill structures and the plurality of vertical support structures are arranged in a surface pattern that defines a plurality of semiconductor device areas.

7. The three-dimensional semiconductor device of claim 6, wherein the surface pattern defines a plurality of rectangles,
wherein the plurality of vertical support structures are arranged along a first edge of a given rectangle,
and wherein the plurality of vertical fill structures are arranged along a second edge, a third edge, and a fourth edge of the given rectangle.

8. The three-dimensional semiconductor device of claim 1, wherein the plurality of epitaxial heterostructures form a three-dimensional dynamic random access memory.

9. A method of forming a three-dimensional semiconductor device, comprising:
providing a monocrystalline semiconductor substrate;
growing an epitaxial macrostack on the monocrystalline semiconductor substrate, the epitaxial macrostack comprising a set of monocrystalline semiconductor layers that alternate with a set of semiconductor alloy layers;
etching an array of slots to form an array of trenches that extend through the epitaxial macrostack;
selectively etching the epitaxial macrostack to remove the set of semiconductor alloy layers, wherein the epitaxial macrostack forms a monocrystalline semiconductor layer stack comprising a set of semiconductor layers that are separated from one another by a set of lateral cavities;
selectively etching a main surface of the set of monocrystalline semiconductor layers, wherein a height of the set of lateral cavities is increased, so as to form a set of device regions; and
growing an epitaxial device heterostructure on exposed surfaces of the set of semiconductor layers within the set of device regions.

10. The method of claim 9, further comprising filling a first set of the array of trenches with a support material to form a plurality of vertical support structures, before selectively etching the epitaxial macrostack.

11. The method of claim 9, further comprising: processing the epitaxial device heterostructure to form a plurality of devices within the set of device regions.

12. The method of claim 9, wherein the substrate comprises monocrystalline silicon having a first main surface parallel to a (100) crystallographic plane, wherein the set of monocrystalline semiconductor layer comprises silicon, and
wherein the epitaxial device heterostructure comprises a Si/SiGe structure.

13. The method of claim 10, wherein the plurality of vertical fill structures comprise an outer layer of epitaxial silicon and an inner layer of silicon nitride.

14. The method of claim 10, wherein the array of slots form a surface pattern that defines a set of semiconductor device areas.

15. The method of claim 14 wherein the surface pattern defines a plurality of rectangles,
wherein the plurality of vertical support structures are arranged along a first edge of a given rectangle,
and wherein the plurality of vertical fill structures are arranged along a second edge, a third edge, and a fourth edge of the given rectangle.

16. The method of claim 9, wherein the epitaxial device heterostructure forms a plurality of epitaxial heterostructures that form a three-dimensional dynamic random access memory.

17. A three-dimensional memory device, comprising:
a silicon substrate;
a monocrystalline semiconductor layer stack, comprising: a plurality of monocrystalline silicon layers, disposed over a main surface of the silicon substrate, and separated from one another; and
a plurality of epitaxial heterostructures, integrally grown from the plurality of monocrystalline silicon layers, wherein a first epitaxial heterostructure is disposed on a lower surface of a given monocrystalline silicon layer, and wherein a second epitaxial heterostructure is disposed on an upper surface of the monocrystalline silicon layer, opposite the lower surface.

18. The three-dimensional memory device of claim 17, wherein the plurality of epitaxial heterostructures comprise a Si/SiGe memory stack, the Si/SiGe memory stack having two or four layers, wherein a given heterostructure of the plurality of epitaxial heterostructures comprises up to 32 Si/SiGe memory stacks.

19. The three-dimensional memory device of claim 17, wherein the plurality of monocrystalline silicon layers individually comprise a thickness of 1 mm to 5 mm.

20. The three-dimensional memory device of claim 17, wherein the plurality of monocrystalline silicon layers comprise up to five layers.
